(19) United States
(12) Patent Application Publication
(10) Pub. No.: US 2011/0298130 A1
(43) Pub. Date: Dec. 8, 2011

(54) SEMICONDUCTOR DEVICES WITH THROUGH-SILICON VIAS

(75) Inventor: Uk-song Kang, Seongnam-si (KR)

(73) Assignee: SAMSUNG ELECTRONICS CO., LTD., Suwon-si (KR)

(21) Appl. No.: 13/093,439

(22) Filed: Apr. 25, 2011

(30) Foreign Application Priority Data
Jun. 8, 2010 (KR) 10-2010-0054055

(51) Int. Cl. H01L 23/48; H01L 23/498

(52) U.S. Cl. 257/738; 257/774; 257/E23.011; 257/E23.069

(57) ABSTRACT

Through silicon vias (TSVs) include a first metal plug having a cylindrical shape, passing through a semiconductor substrate, and with an outer peripheral surface surrounded by a first insulating film; an isolated semiconductor substrate in the semiconductor substrate and surrounding a first metal plug surrounded by a first insulating film; and a second metal plug surrounding the isolated semiconductor substrate and being surrounded by a second insulating film. A first bias voltage is applied to the isolated semiconductor substrate so that a depletion layer is formed in the isolated semiconductor substrate from an interface between the isolated semiconductor substrate and the first insulating film. The first bias voltage is different from a second bias voltage applied to the semiconductor substrate, which is a main semiconductor substrate, with a device forming area where transistors constituting circuits are formed.

### CROSS-REFERENCE TO RELATED APPLICATION

This application claims priority under 35 U.S.C. §119 to Korean Patent Application No. 10-2010-0054055, filed on Jun. 8, 2010, in the Korean Intellectual Property Office (KIPO), the entire contents of which is incorporated herein by reference.

### BACKGROUND

Example embodiments of the inventive concepts relate to semiconductor devices, and more particularly, to semiconductor devices with through-silicon vias (TSVs), the positions and structures of TSVs, and methods of biasing regions around TSVs.

As digital information devices, such as mobile phones, digital cameras, and personal digital assistants (PDAs), have a smaller design, increased functionality, and higher performance, semiconductor packages may be required to have a smaller and thinner design and higher integration density. In this regard, a three-dimensional (3D) semiconductor technology stacking a plurality of semiconductor chips in one package may increase integration density. In a 3D semiconductor device, wiring may be in-plane wiring, which is provided on a surface of a chip, and inter-chip wiring, which is provided between chips. Examples of inter-chip wiring include through-wiring using a through-silicon via (TSV) that passes completely through a substrate from a front surface to a rear surface of the substrate.

### SUMMARY

Example embodiments of the inventive concepts may provide semiconductor devices in which chip size overhead may be reduced by using through-silicon vias (TSVs). According to example embodiments of the inventive concepts, semiconductor devices including TSVs with reduced parasitic capacitance may be provided.

According to example embodiments of the inventive concepts, there may be provided semiconductor devices including TSVs and pads, and the TSVs may be disposed under the pads.

The TSV may be an internal node of a circuit in the semiconductor device. The TSV may be electrically separated from the pad. The TSV may be a power node of the semiconductor device. The TSV may be directly connected to the pad. The TSV may have a cylindrical structure. The TSV may have a ring-type structure. The TSV may include: a semiconductor substrate; a first metal plug having a cylindrical shape, passing through the semiconductor substrate, and having an outer peripheral surface surrounded by a first insulating film; an isolated semiconductor substrate disposed in the semiconductor substrate and surrounding the first metal plug surrounded by the first insulating film; and a second metal plug passing through the semiconductor substrate, surrounding the isolated semiconductor substrate, and being surrounded by a second insulating film. A first bias voltage is applied to the isolated semiconductor substrate so that a depletion layer is formed in the isolated semiconductor substrate, from an interface between the isolated semiconductor substrate and the first insulating film. The first bias voltage is different from a second bias voltage applied to the semiconductor substrate.

The first bias voltage may be a negative voltage. The first bias voltage may be a voltage used to form an inversion layer on the interface between the first insulating film and the isolated semiconductor substrate. The second bias voltage may be a ground voltage. A ground voltage may be applied to the second metal plug. The TSV may include: a semiconductor substrate; a metal plug having a ring-shape, passing through the semiconductor substrate, and having inner and outer peripheral surfaces surrounded by an insulating film; and an isolated semiconductor substrate disposed in the semiconductor substrate and inside the metal plug surrounded by the insulating film. A first bias voltage may be applied to the isolated semiconductor substrate so that a depletion layer is formed in the isolated semiconductor substrate, from an interface between the isolated semiconductor substrate and the insulating film. The first bias voltage may be different from a second bias voltage applied to the semiconductor substrate.

The TSV may include a semiconductor substrate; a first metal plug having a ring-shape, passing through the semiconductor substrate, and having internal and outer peripheral surfaces surrounded by a first insulating film; a first isolated semiconductor substrate disposed in the semiconductor substrate and inside the first metal plug surrounded by the first insulating film; a second isolated semiconductor substrate disposed in the semiconductor substrate and surrounding the first metal plug surrounded by the first insulating film; and a second metal plug passing through the semiconductor substrate, surrounding the second isolated semiconductor substrate, and being surrounded by a second insulating film. A first bias voltage may be applied to the first and second isolated semiconductor substrates so that a depletion layer is formed in the first and second isolated semiconductor substrates, from an interface between the first and second isolated semiconductor substrates and the first insulating film. The first bias voltage may be different form a second bias voltage applied to the semiconductor substrate. The pad may not be tested during a wafer test performed on the semiconductor device.

According to further example embodiments, a semiconductor device includes a pad and a through-silicon via (TSV) under the pad.

According to still further example embodiments, a semiconductor device includes a through silicon via (TSV) including a semiconductor layer at least one of surrounding an outer sidewall of a conductive layer and surrounded by an inner sidewall of the conductive layer.

### BRIEF DESCRIPTION OF THE DRAWINGS

Example embodiments of the inventive concepts will be more clearly understood from the following brief description taken in conjunction with the accompanying drawings. FIGS. 1-12 represent non-limiting, example embodiments as described herein.

FIG. 1 is a cross-sectional diagram illustrating semiconductor devices according to example embodiments of the inventive concepts;

FIG. 2 is a block diagram illustrating upper end surfaces of pads of a first chip of a semiconductor device of FIG. 1;

FIG. 3 is a cross-sectional diagram illustrating semiconductor devices according to other example embodiments of the inventive concepts;

FIG. 4 is a cross-sectional schematic illustrating a structure of a through-silicon via (TSV) of a semiconductor device of FIG. 3 according to example embodiments of the inventive concepts;

FIG. 5 is cross-sectional diagram and an equivalent circuit illustrating parasitic capacitance of a TSV of FIG. 3;

FIG. 6A is a graph of depletion layer thickness (cm) as a function of bias voltage (V) applied to a semiconductor substrate;

FIG. 6B is a graph of a capacitance ratio C/C0 as a function of bias voltage applied to a semiconductor substrate;

FIG. 7 is a plan view illustrating an upper end surface of a structure of a TSV of a semiconductor device of FIG. 3;

FIGS. 8A-8F are cross-sectional diagrams illustrating methods of manufacturing a TSV of FIG. 3;

FIG. 9 is a cross-sectional schematic illustrating a structure of a TSV of FIG. 3, according to still other example embodiments of the inventive concepts;

FIG. 10 is a plan view illustrating an upper end surface of a structure of a TSV of FIG. 9;

FIG. 11 is a cross-sectional schematic illustrating a structure of a TSV of FIG. 3 according to yet other example embodiments of the inventive concepts; and

FIG. 12 is a plan view illustrating an upper end surface of a structure of a TSV of FIG. 11.

It should be noted that these figures are intended to illustrate the general characteristics of methods, structure and/or materials utilized in certain example embodiments of the inventive concepts and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments of the inventive concepts to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

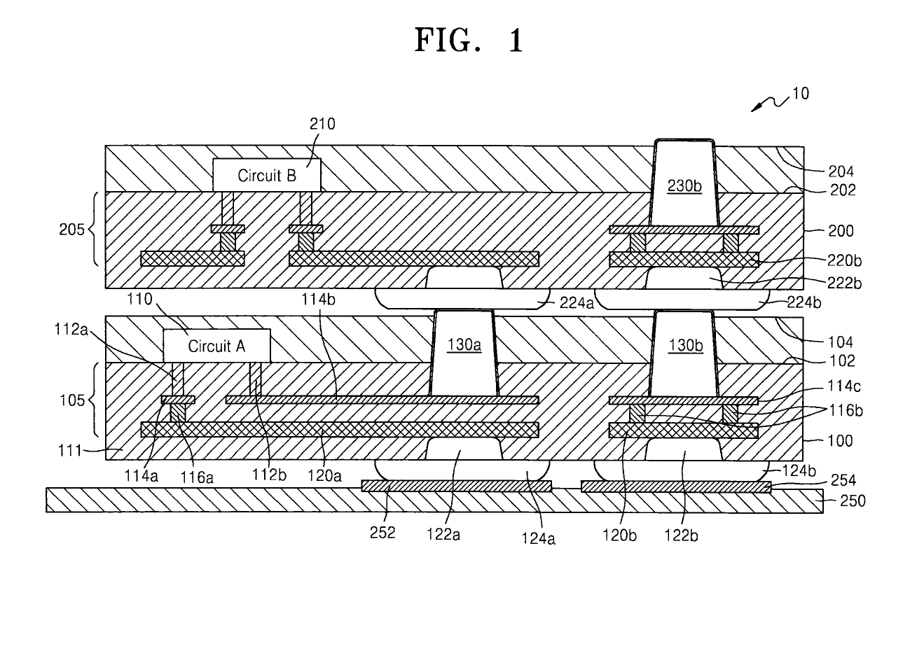

FIG. 1 is a cross-sectional diagram of a semiconductor device 10 according to example embodiments of the inventive concepts. Referring to FIG. 1, a semiconductor device 10 may include a first chip 100 and a second chip 200 stacked on a printed circuit board (PCB) 250. Example embodiments are not limited thereto, and for example, three or more chips may be stacked on a PCB 250. The first and second chips 100 and 200 may include first surfaces 102 and 202, which are upper end surfaces, and second surfaces 104 and 204, which are lower end surfaces, respectively. Circuits 110 and 210 of the first and second chips 100 and 200 may be respectively on the first surfaces 102 and 202, and the second surfaces 104 and 204 may be wafer rear surfaces of the first and second chips 100 and 200.

Signal lines of the circuit 110 of the first chip 100 may be connected to first metal lines 114a and 114b through first vias 112a and 112b filled with, for example, a conductive material. The first metal line 114a may be connected to a second metal line 120a through a second via 116a filled with, for example, a conductive material. The second metal line 120a may be a pad of the first chip 100. The second metal line 120a of the first chip 100 may be connected to a solder ball 124a through an electrode pad 122a. The solder ball 124a may be connected to an electrode pad 252 of the PCB 250. The first via 112b connected to the circuit 110 of the first chip 100 may be connected to the first metal line 114b, and the first metal line 114b may be connected to a through-silicon via (TSV) 130a. The TSV 130a may be under the second metal line 120a and may not be directly connected to the second metal line 120a. The TSV 130a may be electrically separated from the second metal line 120a. The TSV 130a may be an internal node TSV.

A second metal line 120b, which may be a pad for supplying power to the first chip 100, may be connected to a solder ball 124b through an electrode pad 122b. The solder ball 124b may be connected to an electrode pad 254 of the PCB 250. The second metal line 120b may be connected to a first metal line 114c through second vias 116b filled with, for example, a conductive material. The first metal line 114c may be connected to a TSV 130b. The second metal line 120b may be directly connected to the TSV 130b. The TSV 130b may be a power TSV. In the first chip 100, the first vias 112a and 112b, the first metal lines 114a, 114b, and 114c, the second metal lines 120a and 120b, and the electrode pads 122a and 122b may be an in-plane wiring 105 and may be separated by different insulating films. For convenience, hereinafter it may be assumed that the first vias 112a and 112b, the first metal lines 114a, 114b, and 114c, the second metal lines 120a and 120b, and the electrode pads 122a and 122b are separated by one interlayer insulating film 111.

Each of the TSVs 130a and 130b may be of cylindrical shape. The second metal lines 120a and 120b over the TSVs 130a and 130b may not be tested during a wafer test performed on the first chip 100. This may be because the TSVs 130a and 130b under the second metal lines 120a and 120b may be damaged due to a probe mark generated thereon during the wafer test. The second chip 200 may be a chip different from the first chip 100. The circuit 210 of the second chip 200 may be different from the circuit 110 of the first chip 100. Solder balls 224a and 224b of the second chip 200 may be respectively connected to the TSVs 130a and 130b of the first chip 100, and may also be connected to the circuit 210 through an in-plane wiring 205.

The solder ball 224b of the second chip 200 may be connected to a TSV 230B through a pad 220b and an electrode pad 222b in the second chip 200. Positions of the TSV 130b under the second metal line 120b of the first chip 100 and the TSV 230b under the pad 220b of the second chip 200 may correspond to each other. The PCB 250 may be a board of a system on which the semiconductor device 10 is mounted. The PCB 250 may be an interposer chip contacting a semiconductor chip. The PCB 250 may be a package substrate of the semiconductor substrate 10.

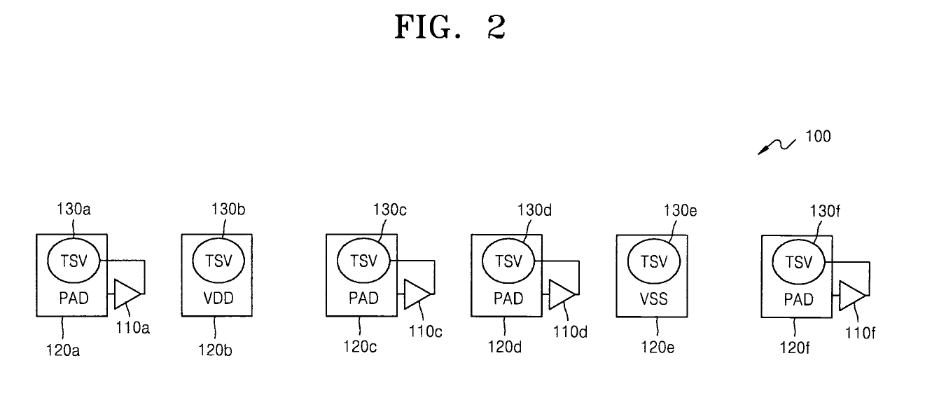

FIG. 2 is a block diagram illustrating upper end surfaces of pads of a first chip 100 of a semiconductor device of FIG. 1. Referring to FIG. 2, TSVs 130a-130f may be under pads 120a-120f of the first chip 100. The first, third, fourth, and sixth pads 120a, 120c, 120d, and 120f are respectively connected to the TSVs 130a, 130c, 130d, and 130f through circuit 110a, 110c, 110d, and 110f, and the second and fifth pads 120b and 120e may be respectively directly connected to the TSVs 130b and 130e. Each of the TSVs 130a, 130c, 130d, and 130f may be an internal node of the first chip 100, and each of the TSVs 130b and 130e may be a power node of the first chip 100. Because the TSVs 130a-130f may be under the pads 120a-120f, an area where the TSVs 130a-130f may be positioned may be separated from the pads 120a-120f, thereby reducing the risk of increasing a chip size.

Referring to FIG. 1, a through-wiring using the TSVs 130a and 130b and an in-plane wiring may be very different in terms of electrical characteristics. In general, the in-plane wiring may be a width of less than 1 μm, whereas the TSVs 130a and 130b may be a width of, for example, greater than 10 um. The reason why the TSVs 130a and 130b may be a greater width is that it may be difficult to form a through-hole with high precision and high aspect ratio in a semiconductor substrate during a semiconductor manufacturing process.

In general, a wiring resistance may be inversely proportional to the cross-sectional area of a wiring. The wiring resistance of the TSVs 130a and 130b with a higher cross-sectional area may be less than that of the in-plane wiring. A parasitic capacitance between a wiring and a semiconductor substrate may be proportional to the area of the semiconductor substrate facing the wiring. A parasitic capacitance between a semiconductor substrate and the TSVs 130a and 130b may be greater than that between a semiconductor substrate and the in-plane wiring. The TSV 130a acting as an internal node of the first chip 100 may be used to transmit a clock signal, a control signal and/or data. Unless a parasitic capacitance of the TSV 130a is charged and discharged whenever a signal is transmitted, the signal may not be transmitted at high speed. Consumed power may increase in proportion to parasitic capacitance. The parasitic capacitance of the TSV 130a may need to be as small as possible.

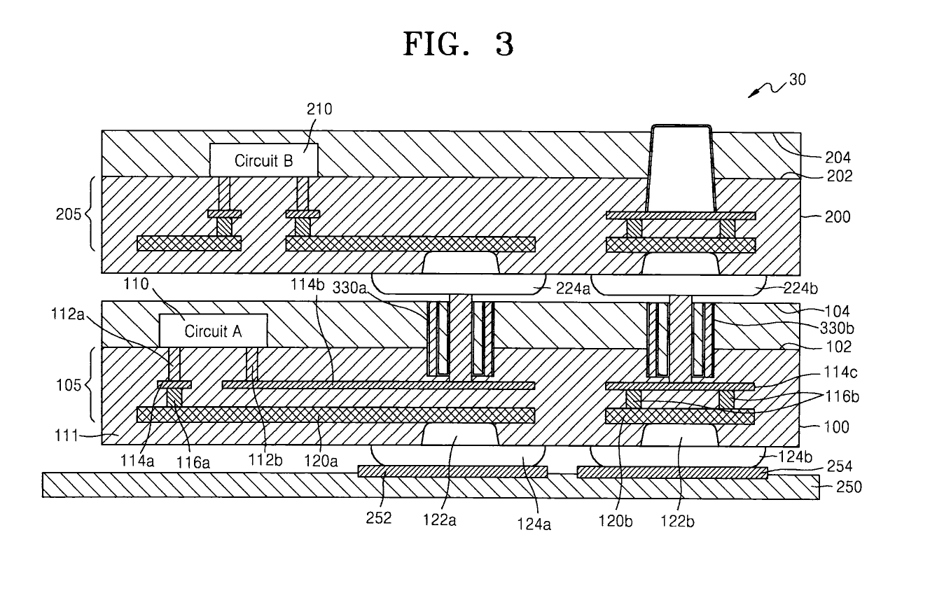

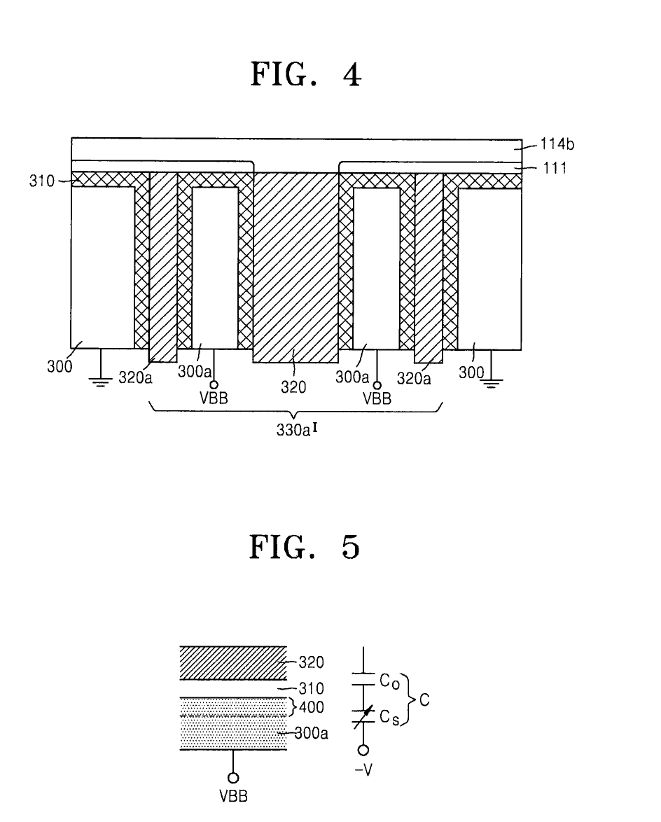

FIG. 3 is a cross-sectional diagram illustrating a semiconductor device 30 according to other example embodiments of the inventive concepts. Referring to FIG. 3, the semiconductor device 30 may be the same or similar to the semiconductor device 10 in FIG. 1. Ring shaped TSVs 330a and 330b may be included. The same elements as in FIG. 1 may not be explained again. FIG. 4 is a cross-sectional schematic illustrating structures of a through-silicon via (TSV) of a semiconductor device 30 of FIG. 3 according to example embodiments of the inventive concepts. Referring to FIG. 4, the TSV 330a^{I} may include a first metal plug 320 with a cylindrical shape inserted into a semiconductor substrate 300 in a thickness direction of the semiconductor substrate 300, and an insulating film 310 along an outer peripheral surface of the first conductive plug 320. The first metal plug 320 may be connected to the first metal line 114b in the interlayer insulating film 111. The first metal plug 320 with the insulating film 310 may be surrounded by an isolated semiconductor substrate 300a. The isolated semiconductor substrate 300a may be separated from the semiconductor substrate 300, which may be a main semiconductor substrate, and may include a device area including circuits. A second metal plug 320a surrounded by the insulating film 310 may be formed between the isolated semiconductor substrate 300a and the semiconductor substrate 300.

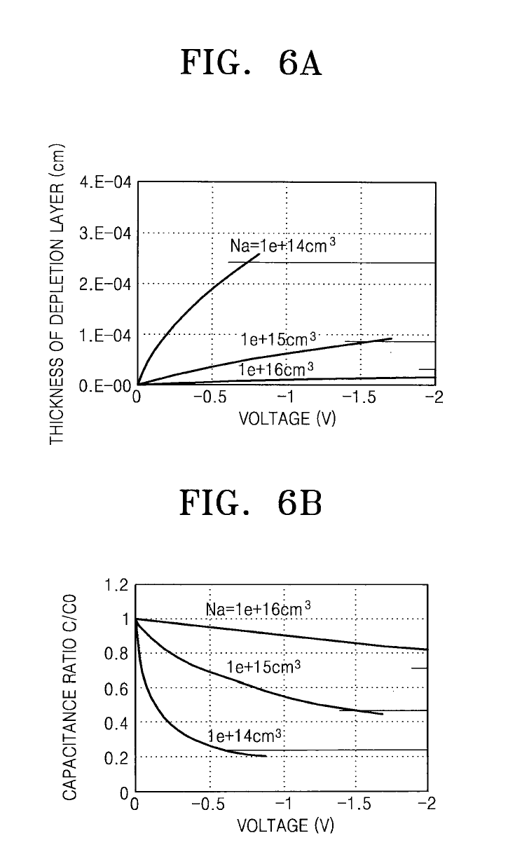

A negative bias voltage VBB may be applied to the isolated semiconductor substrate 300a. As illustrated in FIG. 5, a depletion layer 400 may be induced in the isolated semiconductor substrate 300a. Once the depletion layer 400 is induced, a total parasitic capacitance C of the TSV 330a may be given by Equation 1 below, where C0 is a parasitic capacitance between the first metal plug 320 and the semiconductor substrate 300a and CS is a capacitance of the depletion layer 400.

$$\frac{1}{C} = \frac{1}{C 0} + \frac{1}{CS} \qquad [ Equation 1 ]$$

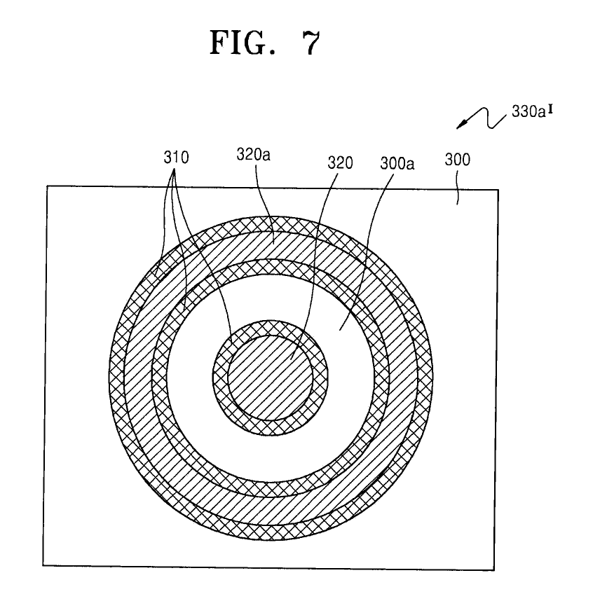

FIG. 6A is a graph illustrating a relationship between the thickness of the depletion layer 400 and a bias voltage VBB applied to the semiconductor substrate 300a. Referring to FIG. 6A, if the bias voltage VBB applied to the semiconductor substrate 300a is constant, a p-type impurity concentration may decrease and the thickness of the depletion layer 400 may increase. In a certain range of concentrations, the thickness of the depletion layer 400 may increase as the absolute value of the bias voltage VBB applied to the semiconductor substrate 300a increases. If the absolute value of the bias voltage VBB applied to the semiconductor substrate 300a exceeds an inversion voltage, an inversion layer may be formed on an interface between the insulating film 310 and the isolated semiconductor substrate 300a. Charges may be accumulated in the inversion layer and may prevent the thickness of the depletion layer 400 from increasing further.

FIG. 6B is a graph illustrating a relationship between a capacitance ratio C/C0 and a bias voltage VBB applied to the semiconductor substrates 300a for different p-type impurity concentrations. Capacitance C0 may be a parasitic capacitance of the TSV 330a when the bias voltage VBB is not applied to the semiconductor substrate 300a, and C may be a parasitic capacitance of the TSV 330a when the bias voltage VBB is applied to the semiconductor substrate 300a. If the semiconductor substrate 300a has a p-type impurity concentration of, for example, 1e15 cm⁻³, a parasitic capacitance of the TSV 330a for a bias voltage VBB of −1V applied to the semiconductor substrate 300a is about 50% less than that when the bias voltage VBB is not applied. A signal may be transmitted to the TSV 330a^{I} at high speed, and power consumption increase during the signal transmission may be prevented and/or reduced.

Referring to FIG. 4, a ground voltage VSS may be applied to the semiconductor substrate 300 including the device area with circuits. Device characteristics of transistors constituting the circuits may be stable. The metal plug 320a between the semiconductor substrate 300 and the isolated semiconductor substrate 300a may be grounded, and may achieve a shielding effect.

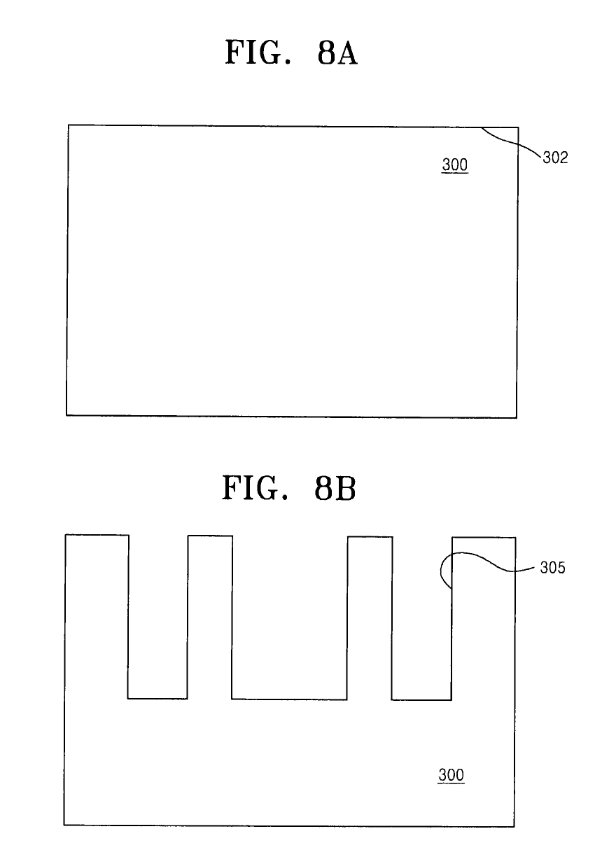

FIG. 7 is a plan view illustrating an upper end surface of a structure of a TSV 330a of a semiconductor device 30 of FIG. 3. Referring to FIG. 7, the TSV 330a^{I} may be a ring-type structure passing through the semiconductor substrate 300, and may include the first metal plug 320, the insulating film 310, the isolated semiconductor substrate 300a, the insulating film 310, the second metal plug 320a, and the insulating film 310 from the center thereof. The first metal plug 320 may be a signal transmission line and a negative bias voltage VBB may be applied to the isolated semiconductor substrate 300a. A ground voltage VSS may be applied to the second metal plug 320a.

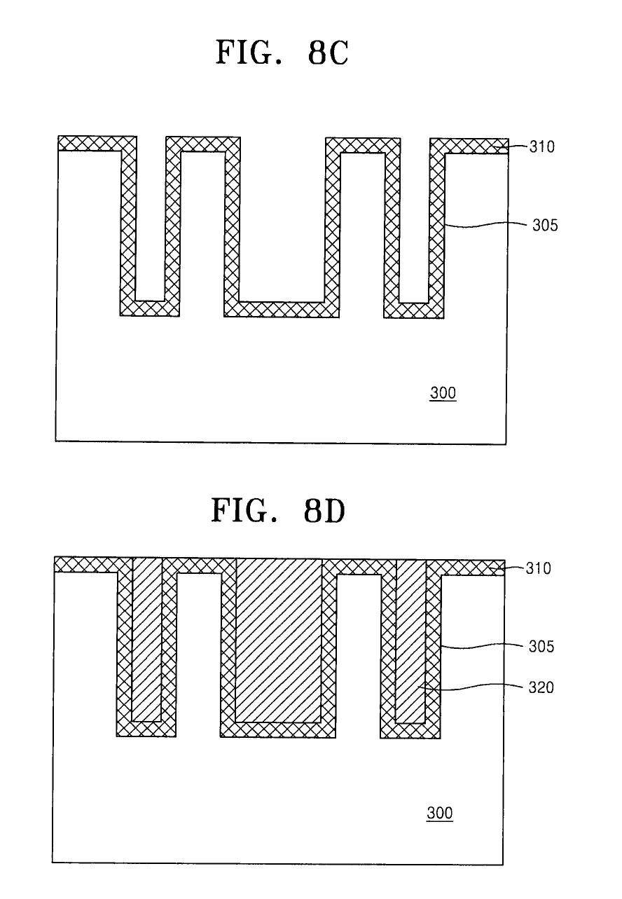

FIGS. 8A-8F are cross-sectional diagrams illustrating methods of manufacturing a TSV 330a^{I} of FIG. 4. Referring to FIG. 8A, a semiconductor substrate 300 in which a TSV 330a^{I} is to be formed may be prepared. Circuits (not shown) may be formed in a device area of an upper end surface 302 of the semiconductor substrate 300. Referring to FIG. 8B, a trench 305 may be formed in a portion of the semiconductor substrate 300 other than the device area. The trench 305 may be formed by, for example, a reactive ion etch (RIE) and/or a laser etch. Referring to FIG. 8C, an insulating film 310 may be formed on an inner surface of the semiconductor substrate 300 in the trench 305 and a surface of the semiconductor substrate 300. The insulating film 310 may have a relatively low dielectric constant. The insulating film 310 may be, for example, formed by vapor chemical deposition and may be, for example, SiO₂, SiN_{X}, TiO₂, and/or Al₂O₃.

Referring to FIG. 8D, a metal plug 320 may be formed in the trench 305 on the insulating film 310. The metal plug 320 may be formed by, for example, sputtering, vapor chemical deposition plating, and/or the like. The trench 305 may be filled by screen printing using a conductive paste. The conductive paste may be, for example, an organic solvent and/or a reducing agent in which fine metal particles having a diameter of tens of nanometers (nm) are dispersed. The fine metal particles of the conductive paste may be, for example, copper (Cu), gold (Au), and/or silver (Ag) particles.

Referring to FIG. 8E, a first metal line 114b contacting the metal plug 320 may be formed. An interlayer insulating film 111 may be coated on the semiconductor substrate 300 in which the metal plug 320 is formed, and an opening of the interlayer insulating film 111 may be formed by dry etching a portion of the interlayer insulating film 111 which is to contact the metal plug 320. The first metal line 114b may be formed on the interlayer insulating film 111 including the opening. The first metal line 114b may be formed of a metal conductive film, for example, a titanium/tungsten (Ti/W) alloy, copper (Cu) and/or aluminum (Al).

Referring to FIG. 8F, a rear surface of the semiconductor substrate 300 of FIG. 8D may be polished by, for example, chemical mechanical polishing (CMP), to expose an end portion of the TSV 330a including the metal plug 320 and the insulating film 310. A layer damaged due to a residual stress on the rear surface of the semiconductor substrate 300 may be removed (not shown). A seed layer formed of a Ti/W alloy or Cu may be formed, a photosensitive resin coated, exposure and developing performed, the seed layer may be etched into a shape, and a Cu layer may be formed by electroplating (not shown). A structure of the TSV 330a^{I} as shown in FIG. 4 may be obtained.

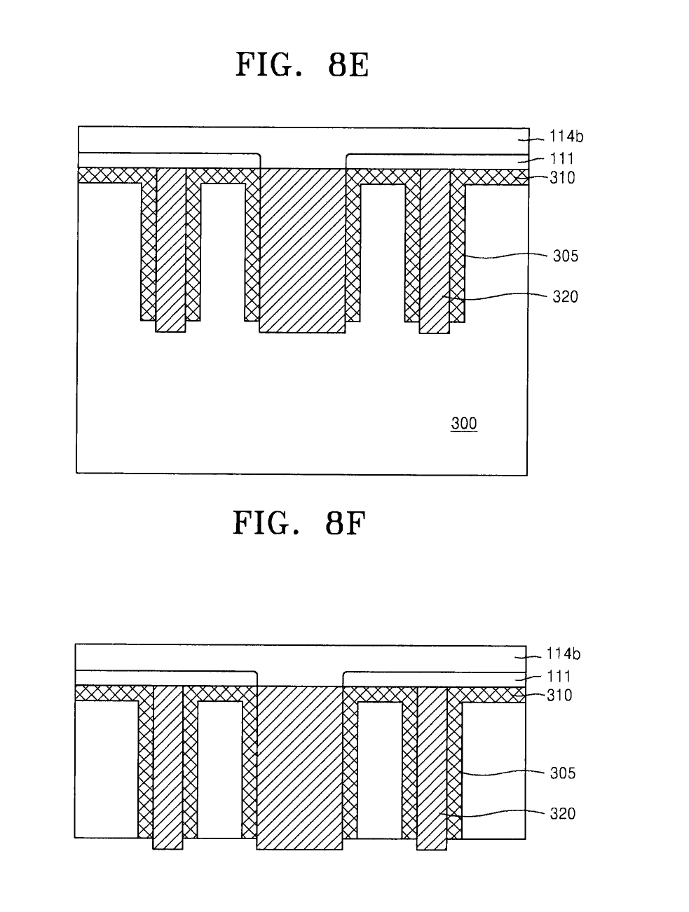

FIG. 9 is a cross-sectional schematic illustrating a structure of a TSV 330a of a semiconductor device 30 according to still other example embodiments of the inventive concepts. Referring to FIG. 9, a TSV 330a^{II} may include a metal plug 920 with a ring-shape inserted into a semiconductor substrate 900 in a thickness direction of the semiconductor substrate 900, and an insulating film 910 along internal and outer peripheral surfaces of the metal plug 920. The metal plug 920 may be connected to the first metal line 114b formed on the interlayer insulating film 111. An isolated semiconductor substrate 900a may be inside the metal plug 920 with the insulating film 310 between the isolated semiconductor substrate 900a and the metal plug 920. The isolated semiconductor substrate 900a may be separated from the semiconductor substrate 900, which is a main semiconductor substrate, including a device area where circuits may be formed.

A negative bias voltage VBB may be applied to the isolated semiconductor substrate 900a and a ground voltage VSS may be applied to the semiconductor substrate 900. As the negative bias voltage VBB is applied to the isolated semiconductor substrate 900a a parasitic capacitance of the TSV 300a may be reduced. A signal may be transmitted to the TSV 330a^{II} at high speed, and power consumption increase during the signal transmission may be prevented and/or reduced. Because the ground voltage VSS may be applied to the semiconductor substrate 900, device characteristics of transistors formed on the semiconductor substrate 900 and constituting the circuits may be stable.

The TSV 330a^{II} of FIG. 9 may be manufactured in the same or similar manner as in the method of manufacturing the TSV 330a^{II} described with reference to FIGS. 8A-8E. The TSV 330a^{II} of FIG. 9 may be different from the TSV of FIGS. 8A-8E in that while one cylindrical trench and one ring-shaped trench 305 may be formed in the semiconductor substrate 300 and the insulating film 310 and the metal plug 320 buried in the two trenches 305 may be formed in FIGS. 8A-8E, one ring-shaped trench may be formed in the semiconductor substrate 900 and then the insulating film 910 and the metal plug 920 may be buried in the one trench according to FIG. 9. A detailed explanation of processes for forming the TSV 330a^{II} of FIG. 9 may not be repeated.

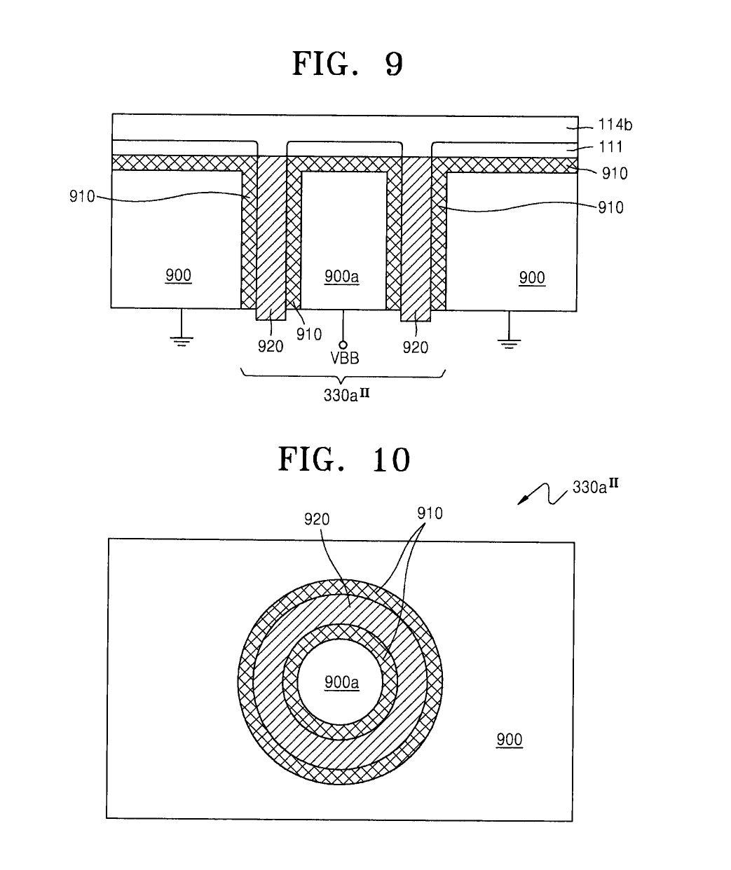

FIG. 10 is a plan view illustrating an upper end surface of a structure of a TSV 330a^{II} of FIG. 9. Referring to FIG. 10, the TSV 330a^{II} may be a ring-type structure passing through a semiconductor substrate 900, and including the isolated semiconductor substrate 900a, the insulating film 910, the metal plug 920, and the insulating film 910 from the center thereof. The metal plug 920 may be a signal transmission line, a negative bias voltage VBB may be applied to the isolated semiconductor substrate 900a and a ground voltage VSS may be applied to the main semiconductor substrate 900.

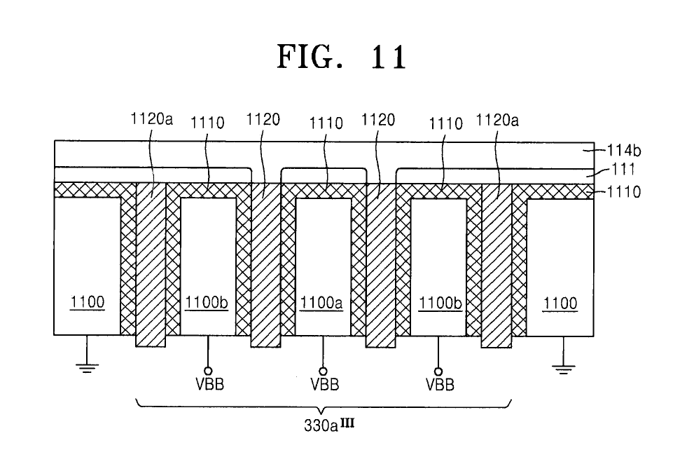

FIG. 11 is a cross-sectional schematic illustrating a structure of a TSV 330a of a semiconductor device 30 of FIG. 3 according to yet other example embodiments of the inventive concepts. Referring to FIG. 11, a TSV 330a^{III} may include first and second metal plugs 1120 and 1120a of ring shapes and inserted into a semiconductor substrate 1100 in a thickness direction of the semiconductor substrate 1100, and an insulating film 1110 along outer peripheral surfaces of the first and second metal plugs 1120 and 1120a. The first metal plug 1120 may contact a first metal line 114b on an interlayer insulating film 111. A first isolated semiconductor substrate 1100a may be inside the first metal plug 1120 with the insulating film 1110 between the first isolated semiconductor substrate 1100a and the first metal plug 1120. A second isolated semiconductor substrate 1100b may be between the first metal plug 1120 and the second metal plug 1120a. The first and second isolated semiconductor substrates 1100a and 1100b may be separated from the semiconductor substrate 1100, which may be a main semiconductor substrate including a device area with circuits.

A negative bias voltage VBB may be applied to the first and second isolated semiconductor substrates 1100a and 1100b, and a ground voltage VSS may be applied to the semiconductor substrate 1100. As the negative bias voltage VBB is applied to the first and second isolated semiconductor substrates 1100a and 1100b, a parasitic capacitance of the TSV 330a may be reduced. A signal may be transmitted to the TSV 330a^{III} at high speed and power consumption increase during the signal transmission may be prevented and/or reduced. Because the ground voltage VSS may be applied to the semiconductor substrate 1100, device characteristics of transistors formed on the semiconductor substrate 1100 and constituting the circuits may be stable. The second metal plug 1120a between the semiconductor substrate 1100 and a ground voltage VSS may be applied to the second isolated semiconductor substrate 1100b, and may achieve a shielding effect.

The TSV 330a^{III} of FIG. 11 may be manufactured in the same or similar manner as that in the method of manufacturing the TSV 330a^{I} described with reference to FIGS. 8A-8E. Methods of manufacturing a TSV 330a^{III} of FIG. 11 may be different from methods of manufacturing a TSV of FIGS. 8A-8E in that while one cylindrical trench and one ring-shaped trench 305 may be formed in the semiconductor substrate 300 and the insulating film 310 and the metal plug 320 buried in the two trenches 305 may be formed in FIGS. 8A-8E, two ring-shaped trenches may be formed in the semiconductor substrate 900, and the insulating film 1110 and the first and second metal plugs 1120 and 1120a may be buried in the two trenches to form a TSV 330a^{III} as illustrated in FIG. 11. A detailed explanation of processes for forming the TSV 330a^{III} of FIG. 11 may not be repeated.

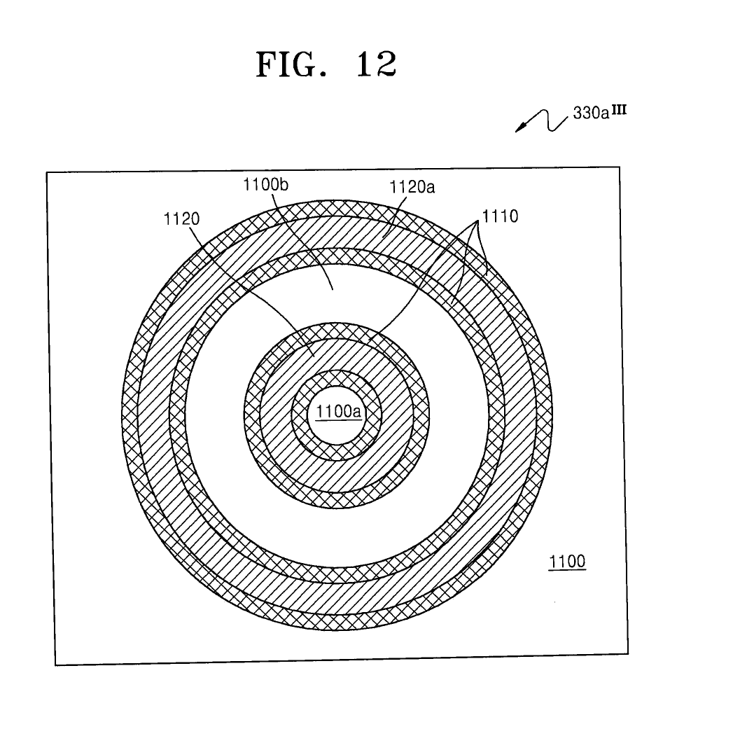

FIG. 12 is a plan view illustrating an upper end surface of a structure of a TSV 330a^{III} of FIG. 11. Referring to FIG. 12, the TSV 330a^{III} with an annular type structure may pass through the semiconductor substrate 1100, and may include a first isolated semiconductor substrate 1100a, an insulating film 1110, a first metal plug 1120, the insulating film 1110, a second isolated semiconductor substrate 1100b, the insulating film 1110, a second metal plug 1120a, and the insulating film 1110 from a center thereof. The first metal plug 1120 may be a signal transmission line. A negative bias voltage VBB may be applied to the first and second separated substrates 1100a and 1100b, and a ground voltage may be applied to the semiconductor substrate 1100. A ground voltage may be applied to the second metal plug 1120a, and may achieve a shielding effect.

While example embodiments have been particularly shown and described, it will be understood by one of ordinary skill in the art that variations in form and detail may be made therein without departing from the spirit and scope of the claims.

What is claimed is:

1. A semiconductor device, comprising:
a pad; and
a through-silicon via (TSV) under the pad.

2. The semiconductor device of claim 1, wherein the TSV is an internal node of a circuit in the semiconductor device.

3. The semiconductor device of claim 2, wherein the TSV is electrically separated from the pad.

4. The semiconductor device of claim 1, wherein the TSV is a power node of the semiconductor device.

5. The semiconductor device of claim 4, wherein the TSV is electrically connected to the pad.

6. The semiconductor device of claim 1, wherein the TSV is a cylindrical structure.

7. The semiconductor device of claim 1, wherein the TSV is a ring-type structure.

8. The semiconductor device of claim 7, wherein the TSV includes
a cylindrical first metal plug,
a first semiconductor layer surrounding an outer peripheral surface of the first metal plug,
a second metal plug surrounding an outer peripheral surface of the first semiconductor layer,
a second semiconductor layer surrounding an outer peripheral surface of the second metal plug, and
at least one insulating layer on the outer peripheral surface of the first metal plug, the at least one insulating layer on inner and the outer peripheral surfaces of the first semiconductor layer and the second metal plug, and the at least one insulating layer on an inner peripheral surface of the second semiconductor layer, and
the TSV is configured to receive a first bias voltage at the first semiconductor layer, the first bias voltage inducing a depletion region in the first semiconductor layer extending from an interface with the first insulating film, and
the TSV is configured to receive a second bias voltage at the second semiconductor layer, the first bias voltage different from the second bias voltage.

9. The semiconductor device of claim 8, wherein the first bias voltage is a negative voltage.

10. The semiconductor device of claim 9, wherein the first bias voltage induces an inversion layer at the interface between the insulating film and the first semiconductor layer.

11. The semiconductor device of claim 8, wherein the second bias voltage is a ground voltage.

12. The semiconductor device of claim 8, wherein the TSV is configured to receive a ground voltage at the second metal plug.

13. The semiconductor device of claim 7, wherein the TSV includes
a first semiconductor layer;
a ring-shaped metal plug surrounding an outer peripheral surface of the first semiconductor layer;
a second semiconductor layer surrounding an outer peripheral surface of the metal plug, and
at least one insulating layer on the outer peripheral surface of the first semiconductor layer, the at least one insulating layer on an inner and the outer peripheral surfaces of the metal plug, and the at least one insulating layer on an inner peripheral surface of the second semiconductor layer, and
the TSV is configured to receive a first bias voltage at the first semiconductor layer, the first bias voltage inducing a depletion region in the first semiconductor layer extending from an interface with the insulating film, and
the TSV is configured to receive a second bias voltage at the second semiconductor layer, the first bias voltage different from the second bias voltage.

14. The semiconductor device of claim 13, wherein the first bias voltage is a negative voltage.

15. The semiconductor device of claim 14, wherein the first bias voltage induces an inversion layer at the interface between the insulating film and the first semiconductor layer.

16. The semiconductor device of claim 13, wherein the second bias voltage is a ground voltage.

17. The semiconductor device of claim 7, wherein the TSV includes
a first semiconductor layer,
a ring-shaped first metal plug on an outer peripheral surface of the first semiconductor layer,
a second semiconductor layer on an outer peripheral surface of the first metal plug,
a second ring-shaped metal plug on an outer peripheral surface of the second semiconductor layer,
a third semiconductor layer on an outer peripheral surface of the second metal plug, and
at least one insulating layer on the outer peripheral surface of the first semiconductor layer, the at least one insulating layer on inner and the outer peripheral surfaces of the first metal plug, the second semiconductor layer, and the second metal plug, the at least one insulating layer on an inner peripheral surface of the third semiconductor layer, and
the TSV is configured to receive a first bias voltage at the first and second semiconductor layers, the first bias voltage inducing depletion regions in the first and second semiconductor layers extending from interfaces between the first and second semiconductor layers and the at least one insulating layer, and
the TSV is configured to receive a second bias voltage at the third semiconductor layer, the first bias voltage different from the second bias voltage.

18. The semiconductor device of claim 17, wherein the first bias voltage is a negative voltage.

19. The semiconductor device of claim 18, wherein the first bias voltage induces an inversion layer at the interfaces between the at least one insulating film and the first and second semiconductor layers.

20. The semiconductor device of claim 17, wherein the second bias voltage is a ground voltage.

21. The semiconductor device of claim 17, wherein the TSV is configured to receive a ground voltage at the second metal plug.

22. The semiconductor device of claim 1, wherein the pad does not include a probe mark.

23. The semiconductor device of claim 1, wherein the TSV contacts a solder ball of a second semiconductor device.

24. The semiconductor device of claim 23, wherein the second semiconductor device includes a second TSV under a pad, the second TSV in contact with a solder ball.

25. A semiconductor device, comprising:
a through silicon via (TSV) including a semiconductor layer at least one of surrounding an outer sidewall of a conductive layer and surrounded by an inner sidewall of the conductive layer.

26. The semiconductor device of claim 25, wherein the conductive layer is part of a signal line.

27. The semiconductor device of claim 25, wherein the conductive layer is part of a power node.

28. The semiconductor device of claim 25, wherein the semiconductor layer is configured to reduce a parasitic capacitance of the TSV.

29. The semiconductor device of claim 28, wherein the semiconductor layer is partially depleted.

30. The semiconductor device of claim 25, wherein the semiconductor layer is a plurality of semiconductor layers,
the conductive layer is between two or more of the semiconductor layers, and
one of the semiconductor layers is a center of the TSV.

31. The semiconductor device of claim 30, wherein the conductive layer is a plurality of conductive layers, and
the conductive layers alternate with the semiconductor layers.

32. The semiconductor device of claim 31, wherein the conductive lines are separated from the semiconductor layers by at least one insulating layer.

33. The semiconductor device of claim 25, wherein the conductive layer is a plurality of conductive layers,
the semiconductor layer is between two of the conductive layers, and
one of the conductive layers is a center of the TSV.
